(19) United States
(12) Patent Application Publication
(10) Pub. No.: US 2009/0176332 A1
(43) Pub. Date: Jul. 9, 2009

(54) MULTI-CHIP DEVICE AND METHOD FOR MANUFACTURING THE SAME

(75) Inventor: Hee Bok KANG, Cheongju-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Hynix Semiconductor Inc.

(21) Appl. No.: 12/404,574

(22) Filed: Mar. 16, 2009

Related U.S. Application Data
(62) Division of application No. 11/525,158, filed on Sep. 22, 2006.

(30) Foreign Application Priority Data
Feb. 17, 2006 (KR) KR10-2006-0015661

(51) Int. Cl. H01L 21/50; H01L 21/768

(52) U.S. Cl. 438/109; 438/637; 438/121; 257/E21.499; 257/E21.597

(57) ABSTRACT

A multi-chip device includes a plurality of chips, a metal pad on a first one of the chips, a through-hole plug electrode in the first one of the chips, a contact node in the first one of the chips connecting the metal pad to the through-hole plug electrode in the first one of the chips, and a connecting ball in the first one of the chips for connecting the through-hole plug electrode in the first one of the chips to a through-hole plug electrode in a second one of the chips.

### RELATED APPLICATION

This application is based upon and claims the benefit of priority to Korean Application No. KR10-2006-0015661, filed on Feb. 17, 2006, the entire contents of which are incorporated herein by reference.

### BACKGROUND

1. Technical Field

The present invention generally relates to a multi-chip device and a method for manufacturing the same, and more specifically, to a technology of performing a through-hole trench process on a wafer and filling the through-hole trench with electrode materials, thereby reducing a layout area.

2. Description of Related Art

A circuit generally includes several chips bonded together with connections provided therebetween. The chips may be bonded by a flip chip process or by a wire bonding process. However, with the wire bonding process, a length of the wire connecting the chips reaches several millimeters. As a result, the number of chips that can be bonded together is limited.

Recently, a technology of forming through-hole electrodes through a chip to provide a transmission path has been developed. Particularly, after a circuit is formed on a wafer, the wafer is polished to less than 100 μm, and through-holes are formed through the wafer and then coated with metal to form connection electrodes.

After chips are formed with the through-hole electrodes, the chips can be connected at certain points with the shortest path. Therefore, the through-hole electrodes through the chips have eliminated the limit of the number of chips that can be bonded together through wire bonding.

Alternative methods for forming connections between a plurality of chips have been developed. For example, when a plurality of chips include small-sized inductors and capacitors for providing transmission through electromagnetic or electrostatic coupling, wireless coupling between the chips may be a substitute for wire bonding or through-hole electrodes.

Techniques for forming circuits in semiconductor chips are key to high performance, low power consumption, and low cost of the circuits. Conventionally, through-hole electrodes are formed after the circuit is completed on a semiconductor chip, and therefore require additional layout space.

### SUMMARY

Various embodiments consistent with the present invention are directed at providing a multi-chip device and a method for manufacturing the same wherein a through-hole trench is formed on a wafer and then filled with electrode materials before a circuit is formed, thereby reducing the whole layout area.

Consistent with embodiments of the present invention, a multi-chip device includes a plurality of chips, a metal pad on a first one of the chips, a through-hole plug electrode in the first one of the chips, a contact node in the first one of the chips connecting the metal pad to the through-hole plug electrode in the first one of the chips, and a connecting ball in the first one of the chips for connecting the through-hole plug electrode in the first one of the chips to a through-hole plug electrode in a second one of the chips.

Consistent with embodiments of the present invention, a multi-chip device includes a plurality of chips. A first one of the chips includes a metal pad; a through-hole plug electrode; a contact node connecting the metal pad to the through-hole plug electrode; and a connecting ball for connecting the through-hole trench plug electrode to a through-hole plug electrode in a second one of the chips.

Consistent with embodiments of the present invention, a method for manufacturing a multi-chip device includes forming a through-hole plug electrode in a wafer for a first chip; forming a circuit on the wafer; forming a metal pad over the wafer; forming a contact node over the wafer for connecting the metal pad to the through-hole plug electrode; and forming a connecting ball over the wafer for connecting the metal pad to a through-hole plug electrode of a second chip.

Consistent with embodiments of the present invention, a method for manufacturing a multi-chip device includes forming a plurality of chips. A first one of the chips is formed by forming a through-hole plug electrode in a wafer; forming a circuit over the wafer; forming a metal pad; forming a contact node for connecting the metal pad to the through-hole plug electrode; and forming a connecting ball for connecting the metal pad to a through-hole plug electrode of a second one of the chips.

### BRIEF DESCRIPTION OF THE DRAWINGS

Other aspects and advantages of the present invention will become apparent upon reading the following detailed description and upon reference to the drawings in which:

FIGS. 1a through 1j are cross-sectional diagrams illustrating a method for manufacturing a chip in a multi-chip device consistent with the present invention; and

FIG. 2 is a cross-sectional diagram illustrating a multi-chip device consistent with the present invention.

### DETAILED DESCRIPTION OF THE EXEMPLARY EMBODIMENTS

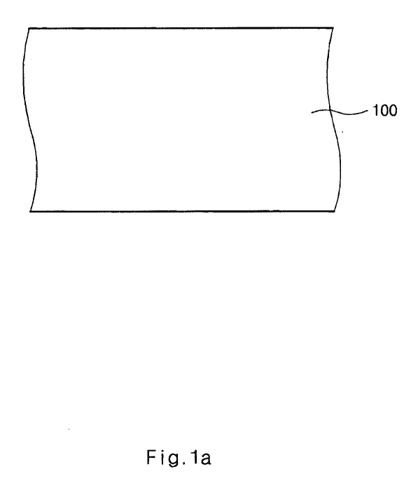

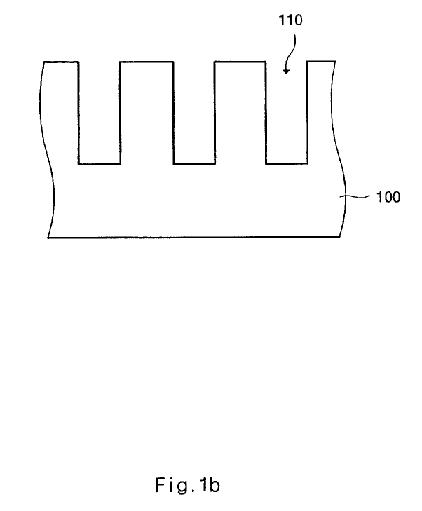

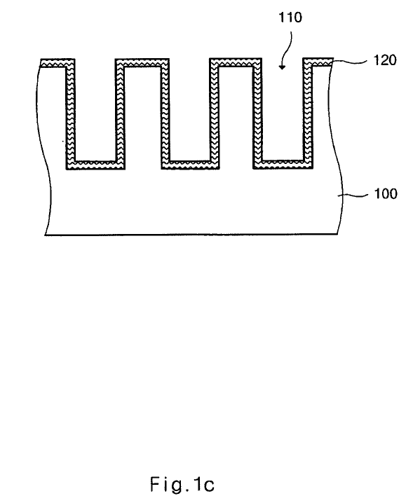

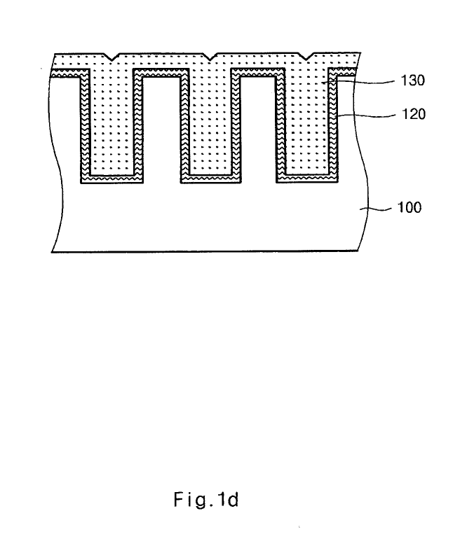

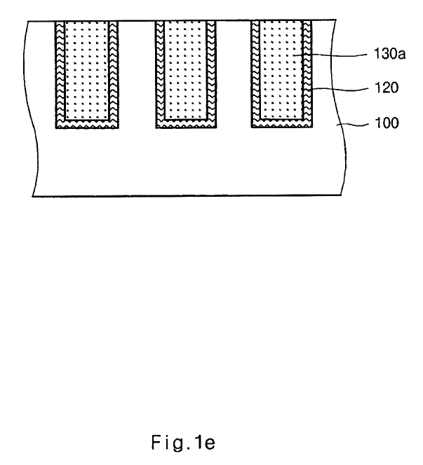

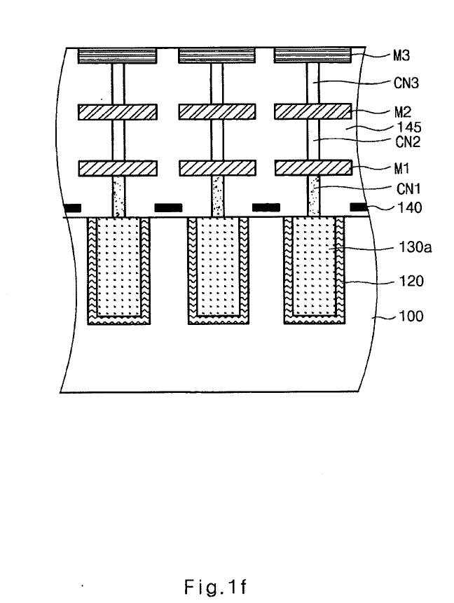

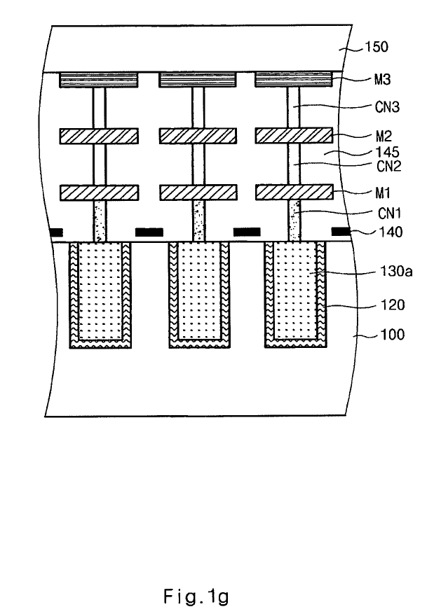

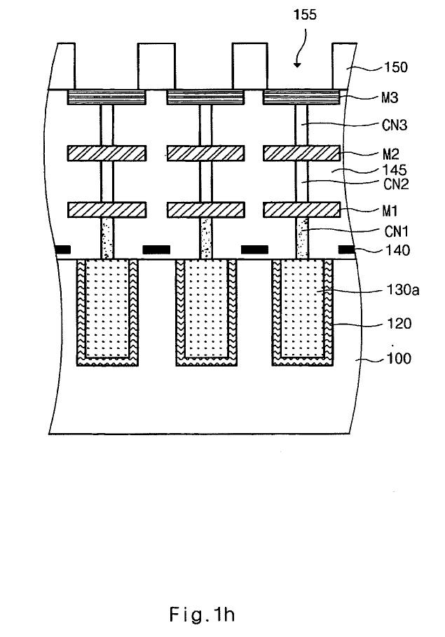

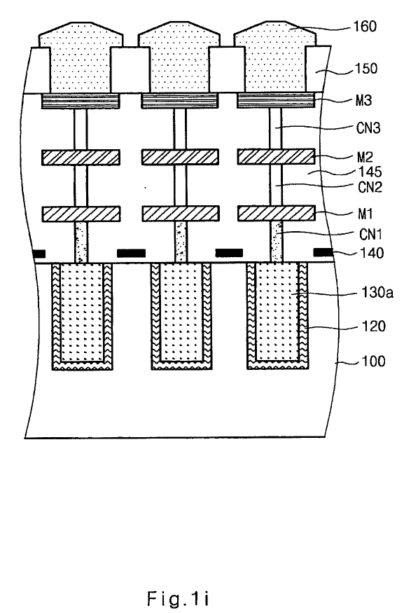

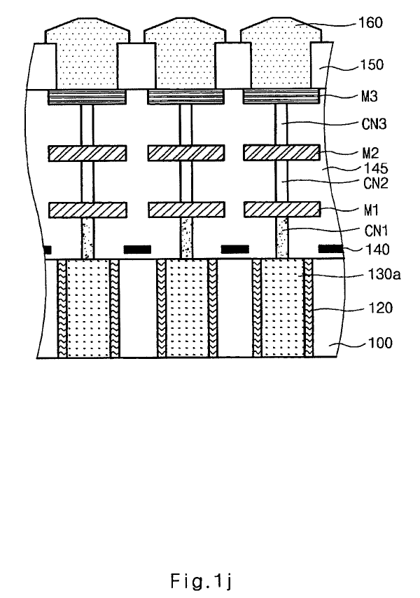

FIGS. 1a through 1j are cross-sectional diagrams illustrating a method for manufacturing a chip in a multi-chip device consistent with the present invention.

FIG. 1a shows a semiconductor wafer 100 before devices are formed thereon.

Referring to FIG. 1b, the semiconductor wafer 100 is selectively etched to form through-hole trenches 110 separated by a predetermined interval.

Referring to FIG. 1c, an insulating film 120 is deposited over the entire surface of the semiconductor wafer 100 including the through-hole trenches 110.

Referring to FIG. 1d, a conductive material is deposited over the entire surface of the resulting structure including the insulating film 120, filling in the through-hole trenches 110, thereby forming a conductive layer 130.

Referring to FIG. 1e, a CMP (Chemical Mechanical Polishing) process, which is a planarization process, is performed to polish the conductive layer 130 to expose the semiconductor wafer 100. As a result of the CMP process, portions of the insulating film 120 and the conductive layer 130 outside the through-hole trenches 110 are removed, forming through-hole plug electrodes 130a.

Circuit elements are then formed on the semiconductor wafer 100. FIGS. 1f-1j show, as an example, MOS transistors formed on the semiconductor wafer 100. For example, referring to FIG. 1f, gate electrodes 140 are formed over the semiconductor wafer 100. Although not shown in the figure, other device components, such as gate dielectric layers, are generally formed below the gate electrodes 140. An insulating film 145 is provided over the entire surface of the resultant structure including the semiconductor wafer 100 and the gate electrodes 140.

FIG. 1f also shows multiple layers of metal contacts may be formed in the insulating film 145 to provide connections to the through-hole plug electrodes 130a. For example, FIG. 1f shows first contact nodes CN1 formed over the through-hole plug electrodes 130a, first metal layers M1 connected to the through-hole plug electrodes 130a through the first contact nodes CN1, second contact nodes CN2 formed over the first metal layers M1, second metal layers M2 connected to the first metal layers M1 through the second contact nodes CN2, third contact nodes CN3 over the second metal layers M2, and third metal layers M3 connected to the second metal layers M2 through the third contact nodes CN3.

Although FIG. 1f shows only the insulating film 140 as one layer, it is to be understood that frequently multiple insulating films are formed during the process of forming the multiple layers of metal contacts.

Referring to FIG. 1g, a passivation layer 150 for protecting the circuit is deposited over the entire surface of the resulting structure.

Referring to FIG. 1h, the passivation layer 150 is selectively etched to form trenches 155 to expose the third metal layers M3.

Referring to FIG. 1i, connecting balls 160 are formed in the trenches 155. The connecting balls 160 may or may not be insulated from one another. Connecting balls 160 respectively connect to the through-hole plug electrodes 130a through the metal contacts M3, M2, M1, and the contact nodes CN3, CN2, CN1.

Referring to 1j, the back side the semiconductor wafer 100 is etched by a back-grinding etching process until the through-hole plug electrodes 130a are exposed.

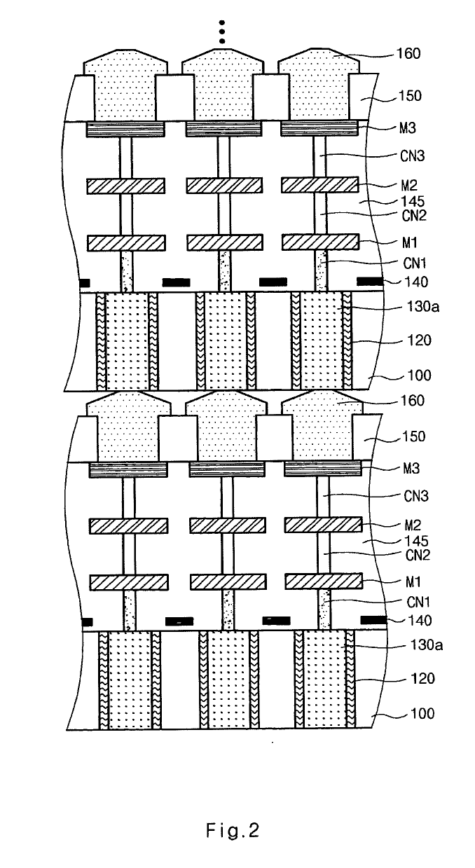

FIG. 2 is a cross-sectional diagram illustrating a multi-chip device consistent with the present invention. The multi-chip device includes chips formed by the method illustrated in FIGS. 1a-1j. As FIG. 2 shows, the chips in the multi-chip device are interconnected through the connections the conductive layer 130 in one chip with the connecting balls 160 in another chip.

As described above, a multi-chip device consistent with the present invention does not require an additional layout space for forming through-hole electrodes, as a result of which a layout area is reduced, and parasitic capacitance and resistance are reduced, thereby improving the operating speed of circuits.

Although FIGS. 1a-1i and 2 show three layers of metal contacts, it is to be understood that the number of layers of metal contacts is not limited to three, but rather may vary depending on the application the device is designed for.

The foregoing description of various embodiments of the invention has been presented for purposes of illustrating and description. It is not intended to be exhaustive or to limit the invention to the precise form disclosed, and modifications and variations are possible in light of the above teachings or may be acquired from practice of the invention. Thus, the embodiments were chosen and described in order to explain the principles of the invention and its practical application to enable one skilled in the art to utilize the invention in various embodiments and with various modifications as are suited to the particular use contemplated.

1-10. (canceled)

11. A method for manufacturing a multi-chip device, comprising:
forming a through-hole plug electrode in a wafer for a first chip;
forming a circuit on the wafer;
forming a metal pad over the wafer;
forming a contact node over the wafer for connecting the metal pad to the through-hole plug electrode; and
forming a connecting ball over the wafer for connecting the metal pad to a through-hole plug electrode of a second chip.

12. The method of claim 11, wherein forming the through-hole plug electrode comprises:
forming a trench in the wafer;
forming an insulating film over the entire surface of the wafer with the trench therein;
depositing conductive materials in the trench; and
performing a planarization process to expose the wafer.

13. The method of claim 12, wherein performing the planarization process comprises performing a CMP (Chemical Mechanical Polishing) process.

14. The method of claim 11, wherein forming the connecting ball comprises:
forming a passivation layer for protecting the circuit over the entire surface of the wafer with the metal pad and the contact node formed thereon;
selectively etching the passivation layer to form a trench to expose the metal pad; and
filling conductive materials in the trench to form the connecting ball.

15. The method of claim 11, further comprising exposing the through-hole plug electrode by a back-grinding etching process of the wafer.

16. A method for manufacturing a multi-chip device, comprising:
forming a plurality of chips, comprising
forming a through-hole plug electrode in a wafer of a first one of the chips;
forming a circuit over the wafer;
forming a metal pad;
forming a contact node for connecting the metal pad to the through-hole plug electrode; and
forming a connecting ball for connecting the metal pad to a through-hole plug electrode of a second one of the chips.

17. The method of claim 16, wherein forming the through-hole plug electrode comprises:
forming a trench in the wafer;
forming an insulating film over the entire surface of the resulting structure;
depositing conductive materials in the trench; and
performing a planarization process to expose the wafer.

18. The method of claim 17, wherein performing the planarization process comprises performing a CMP (Chemical Mechanical Polishing) process.

19. The method of claim 16, wherein forming the connecting ball comprises:
forming a passivation layer for protecting the circuit over the entire surface of the wafer with the metal pad and contact node formed thereon;
selectively etching the passivation layer to form a trench to expose the metal pad; and
filling conductive materials in the trench to form the connecting ball.

20. The method of claim 16, further comprising exposing the through-hole plug electrode by a back-grinding etching process of the wafer.
